(19) United States
(12) Patent Application Publication
(10) Pub. No.: US 2026/0162749 A1
(43) Pub. Date: Jun. 11, 2026

(54) MEMORY DRIVE DEVICE, INFORMATION PROCESSING APPARATUS, AND CONTROL METHOD

(71) Applicant: Lenovo (Singapore) Pte. Ltd., Singapore (SG)

(72) Inventors: Tingting Zhang, Kanagawa (JP); Takashi Sugawara, Kanagawa (JP)

(73) Assignee: Lenovo (Singapore) Pte. Ltd., Singapore (SG)

(21) Appl. No.: 19/317,093

(22) Filed: Sep. 2, 2025

(30) Foreign Application Priority Data
Sep. 6, 2024 (JP) 2024-154057

(51) Int. Cl. G11C 29/44

(52) U.S. Cl. CPC G11C 29/44

(57) ABSTRACT

A memory drive device includes a data storage area, a test storage area, and a controller. The data storage area is composed of rewritable non-volatile memory chips and configured to store data used in information processing. The test storage area is composed of the non-volatile memory chips to store predetermined test data. When date and time information acquired from an upper apparatus is accurate and a power-off period based on the date and time information exceeds a threshold period, the controller determines that a predetermined data retention period has been reached, while when the date and time information is not accurate, the controller determines that the predetermined data retention period has been reached based on an index value related to a storage failure in the test storage area in which the predetermined test data are stored in advance.

### CROSS-REFERENCE TO RELATED APPLICATIONS

This application claims priority to Japanese Patent Application No. 2024-154057 filed on Sep. 6, 2024, the contents of which are hereby incorporated herein by reference in their entirety.

### TECHNICAL FIELD

Embodiments of the present invention relate to a memory drive device, an information processing apparatus, and a control method.

### BACKGROUND

In recent years, a memory drive device such as an SSD (Solid State Drive) has been known (for example, see Japanese Unexamined Patent Application Publication No. 2020-017262). In such a memory drive device, for example, a non-volatile memory such as a NAND type (non-conjunction type) flash memory is used.

Incidentally, in a rewritable non-volatile memory such as a NAND flash memory, written data may be garbled due to the passage of time. The characteristics that cause garbled data due to the passage of time are called retention characteristics, and a period of retaining the data is called a retention period. In the conventional memory drive device described above, it is difficult to grasp how much time has passed since the data was written. Therefore, for example, when the retention period is exceeded, the data may be garbled.

### SUMMARY

Embodiments of the present invention provide a memory drive device, an information processing apparatus, and a control method capable of reducing garbled data due to retention characteristics and improving reliability.

A first aspect of the present invention is a memory drive device having rewritable non-volatile memory chips, the memory drive device including: a data storage area composed of the non-volatile memory chips and capable of storing data used in information processing; a test storage area composed of the non-volatile memory chips to store predetermined test data; and a controller which performs rewriting of already-stored data on the data storage area when a predetermined data retention period has been reached, wherein the controller calculates a power-off period of an upper apparatus based on date and time information acquired from the upper apparatus to which the memory drive device is connected, and when the acquired date and time information is accurate and the power-off period exceeds a threshold period, the controller determines that the predetermined data retention period has been reached, or when the date and time information is not accurate, the controller determines that the predetermined data retention period has been reached based on an index value related to a storage failure in the test storage area in which the predetermined test data are stored in advance.

The memory drive device according to the above aspect of the present invention may be such that the controller calculates the power-off period based on first date and time information as the date and time information acquired from a BIOS (Basic Input Output System) of the upper apparatus upon bootup of the upper apparatus, and second date and time information as date and time information upon power-off of the memory drive device, and the controller determines whether or not the acquired date and time information is accurate based on a time relationship between the first date and time information and the second date and time information.

The memory drive device according to the above aspect of the present invention may also be such that a bit error rate when reading the test data of the test storage area is included as the index value, and when the date and time information is not accurate, the controller determines that the predetermined data retention period has been reached based on the bit error rate as the index value.

The memory drive device according to the above aspect of the present invention may further be such that, when the date and time information is accurate, the controller adopts, as the power-off period, the longer one between a first power-off period calculated based on the first date and time information and the second date and time information, and a second power-off period estimated based on the bit error rate, or when the date and time information is not accurate, the controller adopts the second power-off period as the power-off period, and when the power-off period exceeds the threshold period, the controller determines that the predetermined data retention period has been reached, and performs rewriting of already-stored data on the data storage area.

The memory drive device according to the above aspect of the present invention may further include a warning processing unit which estimates an average ambient temperature of the upper apparatus based on a difference between the first power-off period and the second power-off period when the acquired date and time information is accurate, and when the average ambient temperature is a threshold temperature or higher, the warning processing unit outputs information indicative of a warning to the upper apparatus.

Further, the memory drive device according to the above aspect of the present invention may be such that the controller estimates the second power-off period using an estimation model for estimating the power-off period from the bit error rate, and the memory drive device further includes a correction processing unit which corrects the estimation model so that the first power-off period and the second power-off period match each other when a difference between the first power-off period and the second power-off period is a certain period or more.

Further, the memory drive device according to the above aspect of the present invention may be such that, when the date and time information is not accurate and the bit error rate has reached a predetermined threshold indicating that the predetermined data retention period has been reached, the controller performs rewriting of already-stored data on the data storage area.

Further, the memory drive device according to the above aspect of the present invention may be such that, when the date and time information is not accurate and the amount of change in the bit error rate has reached a predetermined threshold indicating that the predetermined data retention period has been reached, the controller performs rewriting of already-stored data on the data storage area.

Further, the second aspect of the present invention is an information processing apparatus including the above memory drive device, which is the above upper apparatus to execute information processing using data stored in the memory drive device.

Further, the third aspect of the present invention is a control method for a memory drive device having rewritable non-volatile memory chips and including: a data storage area composed of the non-volatile memory chips and capable of storing data used in information processing; and a test storage area composed of the non-volatile memory chips to store predetermined test data, the control method including: causing a controller to calculate a power-off period of an upper apparatus based on date and time information acquired from the upper apparatus to which the memory drive device is connected, and to determine that a predetermined data retention period has been reached when the acquired date and time information is accurate and the power-off period exceeds a threshold period; causing the controller to determine that the predetermined data retention period has been reached based on an index value related to a storage failure in the test storage area in which the predetermined test data are stored in advance when the date and time information is not accurate; and causing the controller to perform rewriting of already-stored data on the data storage area when the predetermined data retention period has been reached.

Embodiments of the present invention can reduce garbled data due to retention characteristics and improve reliability.

### BRIEF DESCRIPTION OF THE DRAWINGS

FIG. 1 is a diagram illustrating an example of a main hardware configuration of an information processing apparatus and an SSD according to a first embodiment.

FIG. 2 is a block diagram illustrating an example of the functional configuration of the SSD according to the first embodiment.

FIG. 3 is a flowchart illustrating an example of the operation of the SSD according to the first embodiment.

FIG. 4 is a flowchart illustrating an example of correction processing of an estimation model of the SSD according to the first embodiment.

FIG. 5 is a flowchart illustrating an example of warning processing of the SSD according to the first embodiment.

FIG. 6 is a block diagram illustrating an example of the functional configuration of an SSD according to a second embodiment.

FIG. 7 is a flowchart illustrating an example of the operation of the SSD according to the second embodiment.

FIG. 8 is a block diagram illustrating an example of an SSD according to a third embodiment.

FIG. 9 is a flowchart illustrating an example of the operation of the SSD according to the third embodiment.

### DETAILED DESCRIPTION

Memory drive devices, an information processing apparatus, and a control method according to embodiments of the present invention will be described below with reference to the accompanying drawings.

### First Embodiment

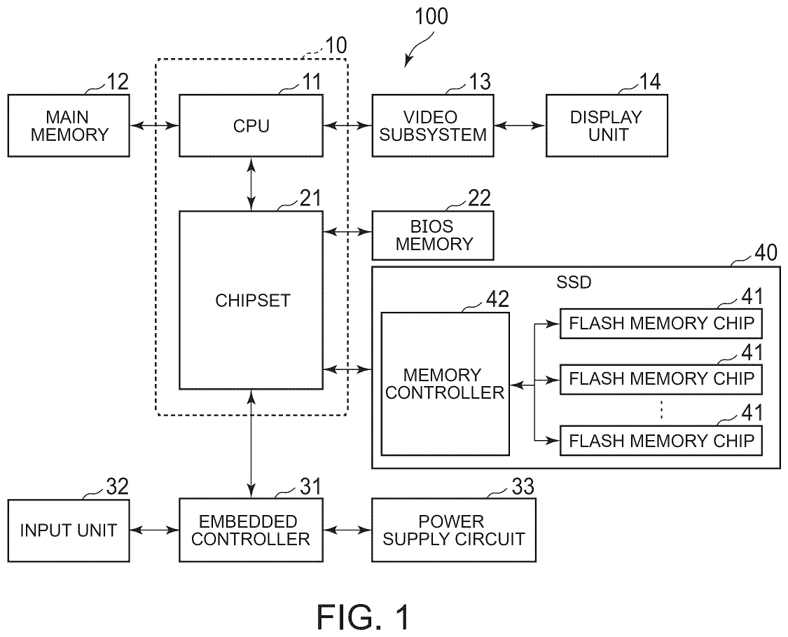

FIG. 1 is a diagram illustrating an example of a main hardware configuration of an information processing apparatus 100 and an SSD 40 according to a first embodiment.

As illustrated in FIG. 1, the information processing apparatus 100 is, for example, a laptop personal computer including a CPU 11, a main memory 12, a video subsystem 13, a display unit 14, a chipset 21, a BIOS memory 22, an embedded controller 31, an input unit 32, a power supply circuit 33, and the SSD 40.

The CPU (Central Processing Unit) 11 executes various arithmetic processes by program control and controls the entire information processing apparatus 100.

The main memory 12 is a writable memory used as reading areas of execution programs of the CPU 11 or working areas to which processed data of the execution programs are written. The main memory 12 is composed, for example, of plural DRAM (Dynamic Random Access Memory) chips. The execution programs include an OS (Operating System), various drivers for hardware-operating peripheral devices, various services/utilities, application programs, and the like.

The video subsystem 13 is a subsystem for implementing a function related to image display, which includes a video controller. This video controller processes drawing instructions from the CPU 11, writes processed drawing information into a video memory, and reads this drawing information from the video memory to output the drawing information to the display unit 14 as drawing data (display data).

The display unit 14 is, for example, a liquid crystal display to display a display screen based on the drawing data (display data) output from the video subsystem 13.

The chipset 21 includes controllers such as USB, serial ATA (AT Attachment), an SPI (Serial Peripheral Interface) bus, a PCI (Peripheral Component Interconnect) bus, a PCI-Express bus, and an LPC (Low Pin Count) bus, and plural devices are connected thereto. In FIG. 1, as examples of devices, the BIOS memory 22 and the SSD 40 are connected to the chipset 21.

Note that the CPU 11 and the chipset 21 correspond to a main control unit 10 (“controller”).

The BIOS (Basic Input Output System) memory 22 is configured, for example, by an electrically rewritable non-volatile memory such as an EEPROM (Electrically Erasable Programmable Read Only Memory) or a flash ROM (flash memory). The BIOS memory 22 stores a BIOS, system firmware for controlling the embedded controller 31, and the like.

The SSD (Solid State Drive) 40 (an example of a memory drive device) is a memory drive device having rewritable non-volatile memory chips, which stores the OS, various drivers, various services/utilities, application programs, and various data. The information processing apparatus 100 executes various information processing using data stored in the SSD 40. The SSD 40 is connected to the chipset 21, for example, through the serial ATA or the PCI-Express bus. Note that the SSD 40 may also be connected to the CPU 11. In the present embodiment, it is assumed that the SSD 40 is connected to the chipset 21 by NVMe connection using the PCI-Express bus.

Further, the SSD 40 includes plural flash memory chips 41 and a memory controller 42.

Each of the flash memory chips 41 is, for example, a NAND flash memory chip, which is an example of each chip of the rewritable non-volatile memory. The flash memory chip 41 writes data (“0”) to or delate data (“1”) from each memory cell by injecting electrons into or extracting electrons from a floating gate of the memory cell. In the flash memory chip 41, since the electrons in the floating gate moves as time passes, data stored in the memory cell may be garbled. The characteristics that cause garbled data due to such a passage of time in the flash memory chip 41 is called retention characteristics, and a period of retaining the data is called a retention period. Further, this retention period tends to be shorter as the temperature increases.

The memory controller 42 is, for example, a processor including a CPU, a ROM, a RAM, and the like, which are not illustrated, to control the SSD 40 comprehensively. For example, the memory controller 42 executes control processing of a host interface (host I/F) with the chipset 21, control processing of a memory interface (memory I/F) with the flash memory chips 41, data management processing of the flash memory chips 41, and the like.

The embedded controller 31 is a one-chip microcomputer which monitors and controls various devices (peripheral devices, sensors, and the like) regardless of the system state of the information processing apparatus 100. Further, the embedded controller 31 has a power management function to control the power supply circuit 33. Note that the embedded controller 31 is composed of a CPU, a ROM, a RAM, and the like, which are not illustrated, and includes multi-channel A/D input terminal and D/A output terminal, a timer, and digital input/output terminals. To the embedded controller 31, for example, the input unit 32, the power supply circuit 33, and the like are connected through these input/output terminals, and the embedded controller 31 controls the operation of these units.

The input unit 32 is, for example, an input unit including a keyboard, a pointing device, a touch pad, and the like.

The power supply circuit 33 includes, for example, a DC/DC converter, a charge/discharge unit, an AC/DC adapter, and the like to convert DC voltage, supplied from an external power supply or a battery, into plural voltages required to operate the information processing apparatus 100. Further, the power supply circuit 33 supplies power to each unit of the information processing apparatus 100 under the control of the embedded controller 31.

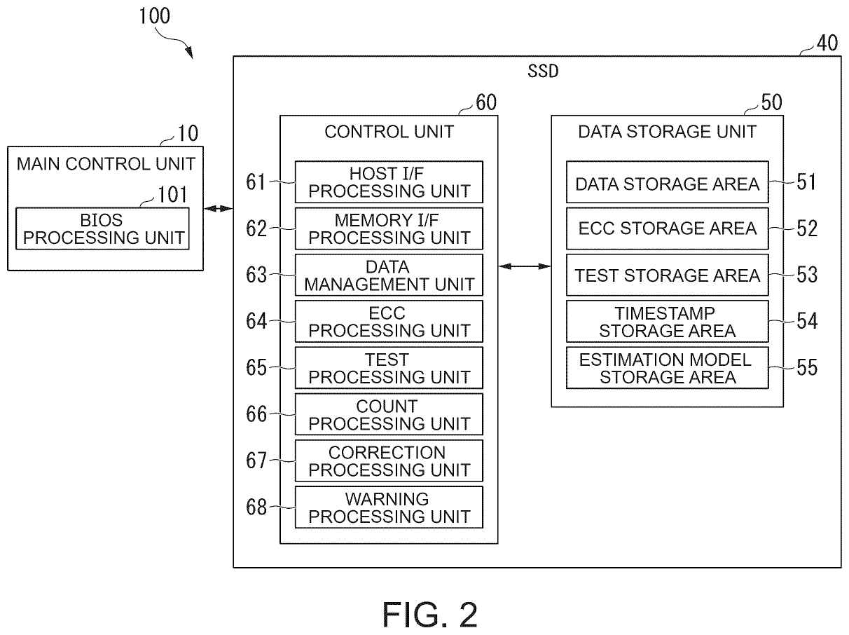

Referring next to FIG. 2, the functional configuration of the SSD 40 according to the present embodiment will be described.

FIG. 2 is a block diagram illustrating an example of the functional configuration of the SSD 40 according to the present embodiment.

As illustrated in FIG. 2, the SSD 40 includes a data storage unit 50 and a control unit 60.

Note that the SSD 40 is connected to the main control unit 10 of an upper apparatus (the information processing apparatus 100) by NVMe connection.

The main control unit 10 is a functional unit implemented by the CPU 11 and the chipset 21 executing programs stored in the main memory 12 to execute various processing based on the OS. For example, the main control unit 10 executes information processing using data stored in the SSD 40. Further, for example, the main control unit 10 boots up the OS (for example, Windows (registered trademark)) by executing a BIOS program. The main control unit 10 includes, for example, a BIOS processing unit 101.

The BIOS processing unit 101 is a functional unit implemented by causing the CPU 11 to execute the BIOS program to execute various BIOS processing. For example, the BIOS processing unit 101 executes processing for booting up the OS. Further, upon starting up the information processing apparatus 100, the BIOS processing unit 101 transmits a timestamp (date and time information) to the SSD 40 by an NVMe Timestamp function.

The data storage unit 50 is a storage unit composed, for example, of the plural flash memory chips 41 described above, which includes, for example, a data storage area 51, an ECC (Error Correction Code) storage area 52, a test storage area 53, a timestamp storage area 54, and an estimation model storage area 55.

The data storage area 51 is composed of the flash memory chips 41, which is a storage area capable of storing data used in information processing. For example, the data storage area 51 stores the OS, various drivers, various services/utilities, application programs, various data, and the like.

The ECC storage area 52 is a storage area composed of the flash memory chips 41 to store error correction codes (ECCs) for correcting errors in data stored in the data storage area 51 and the test storage area 53. For example, in the ECC storage area 52, an error correction code (ECC) corresponding to data is stored when the data is stored in (written into) the data storage area 51 or the test storage area 53.

The test storage area 53 is composed of the flash memory chips 41 to store predetermined test data. The test storage area 53 stores test data for determining whether or not to a predetermined data retention period indicative of a predetermined period from data writing has been reached. For example, in the test storage area 53, test data are stored when the information processing apparatus 100 is shipped. Further, for example, the test data may be resaved (rewritten) into the test storage area 53 when the OS is reinstalled after the information processing apparatus 100 is shipped.

The timestamp storage area 54 is composed of the flash memory chips 41 to store a BIOS timestamp (a timestamp upon bootup) acquired from the BIOS, a timestamp at shutdown (a power-off timestamp), and the like. The timestamp storage area 54 may also store a history of past BIOS timestamps and power-off timestamps.

The estimation model storage area 55 is composed of the flash memory chips 41 to store an estimation model for estimating a power-off lead time from a bit error rate (hereinafter called the BER (Bit Error Rate)) when test data in the test storage area 53 is read out. The power-off lead time indicates a power-off period in the information processing apparatus 100.

The estimation model estimates the power-off lead time from the BER using, for example, Equation (1) indicative of an estimable data retention period (AF) below and past actual values of BERs and power-off lead times.

$$AF = exp \{ \frac{Δ H}{k} [ \frac{1}{T1} - \frac{1}{{T}_{2}} ] \} \qquad ( 1 )$$

Note that in Equation (1), k represents the Boltzmann constant and H represents activation energy. Further, T₁ represents test temperature (43° C.=316.15 K (kelvin)) and T₂ represents actual temperature.

The control unit 60 is a functional unit implemented by the memory controller 42 described above, which executes various processing of the SSD 40. The control unit 60 includes a host I/F processing unit 61, a memory I/F processing unit 62, a data management unit 63, an ECC processing unit 64, a test processing unit 65, a count processing unit 66, a correction processing unit 67, and a warning processing unit 68.

The host I/F processing unit 61 controls an interface between the chipset 21 and the SSD 40. For example, the host I/F processing unit 61 controls the PCI-Express bus (NVMe) interface to accept commands for data writing and reading from the chipset 21. Further, the host I/F processing unit 61 outputs output information, such as data read from the data storage unit 50 and the like, to the chipset 21 through the PCI-Express bus (NVMe) interface. Note that the host I/F processing unit 61 may also control an interface between the CPU 11 and the SSD 40.

The memory I/F processing unit 62 controls an interface between the control unit 60 (the memory controller 42) and the data storage unit 50 (the plural flash memory chips 41). For example, the memory I/F processing unit 62 outputs erase, write, and read commands to the flash memory chips 41 to control the flash memory chips 41.

The data management unit 63 manages a correspondence between the logical address of the SSD 40 used for control from the information processing apparatus 100, and the physical address of the data storage unit 50 (the flash memory chips 41), and manages data stored in the data storage unit 50. The data management unit 63 executes various processing based on various commands from the chipset 21 received by the host I/F processing unit 61.

The ECC processing unit 64 (an example of a correction processing unit) corrects an error in data read from the data storage unit 50 based on an ECC (error correction code). For example, based on the read data and the ECC corresponding to the read data, the ECC processing unit 64 determines whether or not data are garbled, and when garbled data (garbled bits) are occurring, the ECC processing unit 64 executes error correction processing using the ECC to correct the garbled data.

When the SSD 40 has reached the predetermined data retention period, the test processing unit 65 performs rewriting of already-stored data at least on the data storage area 51. For example, the test processing unit 65 determines whether or not to reach the predetermined data retention period by switching between and using a power-off lead time A (a first power-off period) based on the timestamp (the BIOS timestamp) acquired from the main control unit 10 (the upper device), and a power-off lead time B (a second power-off period) based on the BER of the test storage area 53.

The test processing unit 65 calculates a power-off lead time (a power-off period) of the upper device based on the BIOS timestamp (date and time information) acquired from the upper device (the main control unit 10 of the information processing apparatus 100) to which the SSD 40 is connected. For example, the test processing unit 65 calculates the power-off lead time A from a difference between the acquired BIOS timestamp (first date and time information) and a timestamp (a past timestamp such as a power-off timestamp (second power-off period)) stored in the timestamp storage area 54.

Further, the test processing unit 65 estimates the power-off lead time B based on an index value related to a storage failure in the test storage area 53 in which predetermined test data are stored in advance. For example, a bit error rate (BER) when the test data of the test storage area 53 are read is included as the index value. For example, the test processing unit 65 calculates the BER from the test storage area 53, and estimates the power-off lead time B from the calculated BER using the estimation model stored in the estimation model storage area 55.

Further, the test processing unit 65 determines whether or not the acquired BIOS timestamp is accurate. For example, the test processing unit 65 determines whether or not the acquired BIOS timestamp is accurate depending on whether or not there is a contradiction between the acquired BIOS timestamp and the timestamp stored in the timestamp storage area 54. In other words, the test processing unit 65 determines whether or not the acquired BIOS timestamp is accurate based on a time relationship between the BIOS timestamp and the power-off timestamp.

When the BIOS timestamp is not accurate, it is considered, for example, that an RTC (Real Time Clock) equipped in the chipset 21 of the information processing apparatus 100 is reset, a battery (backup power supply) for the RTC is dead, or the like.

When the acquired BIOS timestamp is accurate, the test processing unit 65 adopts the longer one between the power-off lead time A and the power-off lead time B as the power-off lead time. On the other hand, when the acquired BIOS timestamp is not accurate, the test processing unit 65 adopts the power-off lead time B as the power-off lead time.

Further, when the power-off lead time exceeds a threshold period, the test processing unit 65 determines that the predetermined data retention period has been reached, and performs rewriting of already-stored data on the data storage area 51. In other words, when the acquired BIOS timestamp is accurate and the power-off lead time exceeds the threshold period, the test processing unit 65 determines that the predetermined data retention period has been reached, and performs rewriting of already-stored data on the data storage area 51.

The test processing unit 65 saves the data already stored in the data storage area 51 to a buffer storage unit configured by an unillustrated RAM, and rewrites (restores) the data through the memory I/F processing unit 62.

Further, since the test processing unit 65 adopts the power-off lead time B as the power-off lead time when the acquired BIOS timestamp is not accurate, the test processing unit 65 determines that the predetermined data retention period has been reached based on an index value (for example, the BER) related to a storage failure in the test storage area 53 when the acquired timestamp is not accurate.

Note that, when performing rewriting of the already-stored data on the data storage area 51, the test processing unit 65 may also rewrite data in other areas (the test storage area 53, the timestamp storage area 54, the estimation model storage area 55, and the like) together.

The count processing unit 66 stores the acquired BIOS timestamp in the timestamp storage area 54, and counts the date and time from the BIOS timestamp using an internal clock of the SSD 40.

When a difference between the power-off lead time A and the power-off lead time B is a certain period of time or more, the correction processing unit 67 corrects the estimation model so that the power-off lead time A and power-off lead time B match each other. For example, the correction processing unit 67 corrects the estimation model by adjusting the activation energy H in Equation (1) described above so that the power-off lead time A and the power-off lead time B match each other. The correction processing unit 67 stores the corrected estimation model in the estimation model storage area 55.

When the acquired BIOS timestamp is accurate, the warning processing unit 68 estimates an average ambient temperature of the information processing apparatus 100 (upper apparatus) based on the difference between the power-off lead time A and the power-off lead time B. For example, the warning processing unit 68 estimates the average ambient temperature of the information processing apparatus 100 (upper apparatus) using Equation (1) described above. When the average ambient temperature is a threshold temperature or higher, the warning processing unit 68 outputs, to the upper device (the main control unit 10 of the information processing apparatus 100), information indicative of a warning (for example, a message indicative of the warning). Here, for example, the threshold temperature is a predetermined temperature exceeding the upper limit of a guaranteed storage temperature of the SSD 40, and the warning processing unit 68 transmits, as the message indicative of the warning, a message warning that the average ambient temperature exceeding the upper limit of the guaranteed storage temperature has been stored to the main control unit 10, and causes the main control unit 10 to output the message to the information processing apparatus 100.

Next, the operation of the SSD 40 according to the present embodiment will be described with reference to the accompanying drawings.

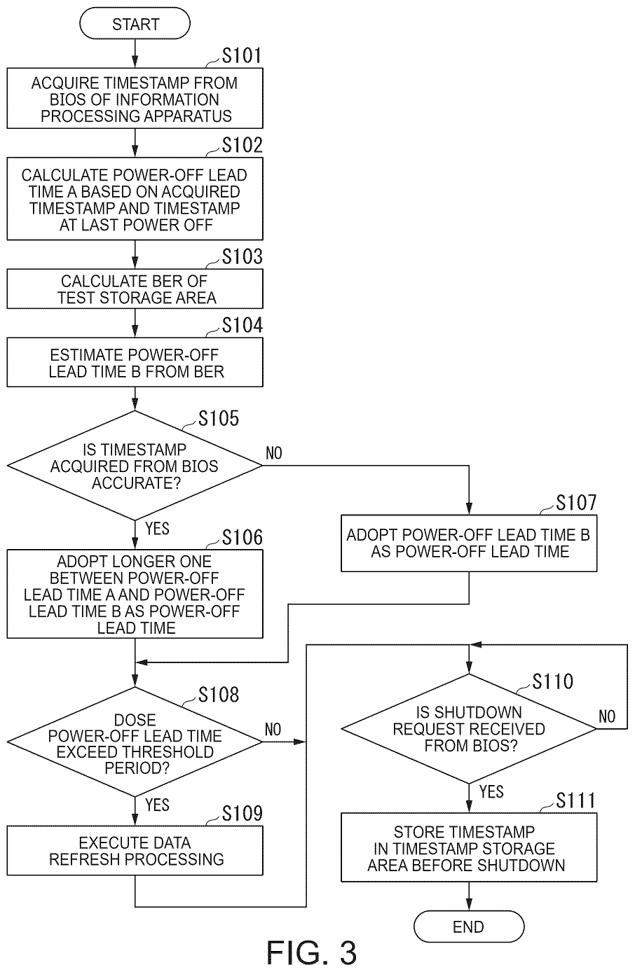

FIG. 3 is a flowchart illustrating an example of the operation of the SSD 40 according to the present embodiment. Here, processing for the SSD 40 to prevent garbled data due to the retention will be described.

As illustrated in FIG. 3, the control unit 60 of the SSD 40 first acquires a timestamp from the BIOS of the information processing apparatus 100 (step S101). The test processing unit 65 of the control unit 60 acquires, as the BIOS timestamp (first date and time information), a timestamp transmitted by the BIOS processing unit 101 of the main control unit 10 using an NVMe Timestamp function. Further, the count processing unit 66 of the control unit 60 stores the acquired BIOS timestamp in the timestamp storage area 54, and counts the date and time from the BIOS timestamp using the internal clock of the SSD 40.

Next, the test processing unit 65 calculates the power-off lead time A based on the acquired timestamp and the timestamp at the last power off (step S102). For example, the test processing unit 65 calculates the power-off lead time A from a difference between the acquired BIOS timestamp and the power-off timestamp stored in the timestamp storage area 54.

Next, the test processing unit 65 calculates the BER of the test storage area 53 (step S103). The test processing unit 65 reads test data in the test storage area 53 through the memory I/F processing unit 62 to calculate the BER.

Next, the test processing unit 65 estimates the power-off lead time B from the BER (step S104). The test processing unit 65 estimates the power-off lead time B from the BER using the estimation model stored in the estimation model storage area 55.

Next, the test processing unit 65 determines whether or not the timestamp acquired from the BIOS is accurate (step S105). For example, the test processing unit 65 determines whether or not the acquired BIOS timestamp is accurate depending on whether or not there is a contradiction between the acquired BIOS timestamp and the timestamp stored in the timestamp storage area 54. In other words, the test processing unit 65 determines whether or not the acquired BIOS timestamp is accurate based on a time relationship between the BIOS timestamp and the power-off timestamp. When the BIOS timestamp is accurate (step S105: YES), the test processing unit 65 advances the processing to step S106. On the other hand, when the BIOS timestamp is not accurate (step S105: NO), the test processing unit 65 advances the processing to step S107.

In step S106, the test processing unit 65 adopts the longer one between the power-off lead time A and the power-off lead time B as the power-off lead time. After the process in step S106, the test processing unit 65 advances the processing to step S108.

Further, in step S107, the test processing unit 65 adopts the power-off lead time B as the power-off lead time. After the process in step S107, the test processing unit 65 advances the processing to step S108.

Next, in step S108, the test processing unit 65 determines whether or not the power-off lead time exceeds the threshold period. When the power-off lead time exceeds the threshold period (step S108: YES), the test processing unit 65 determines that the predetermined data retention period has been reached, and advances the processing to step S109. On the other hand, when the power-off lead time does not exceed the threshold period (when the power-off lead time is the threshold period or less) (step S108: NO), the test processing unit 65 determines that the predetermined data retention period has not been reached, and advances the processing to step S110.

In step S109, the test processing unit 65 executes data refresh processing. For example, the test processing unit 65 saves the data already stored in the data storage area 51 to the buffer storage unit configured by the unillustrated RAM, and rewrites (restores) the data through the memory I/F processing unit 62.

Next, in step S110, the test processing unit 65 determines whether or not a shutdown request is received from the BIOS. The test processing unit 65 determines whether or not a shutdown request command from the BIOS is received through the host I/F processing unit 61. When the shutdown request is received from the BIOS (step S110: YES), the test processing unit 65 advances the processing to step S111. On the other hand, when the shutdown request is not received from the BIOS (step S110: NO), the test processing unit 65 returns the processing to step S110.

In step S111, the test processing unit 65 stores the timestamp in the timestamp storage area 54 before shutdown. The test processing unit 65 stores, in the timestamp storage area 54, the power-off timestamp (second date and time information) counted by the count processing unit 66 using the internal clock of the SSD 40. After the process in step S111, the test processing unit 65 executes a shutdown process of the SSD 40 to end the processing.

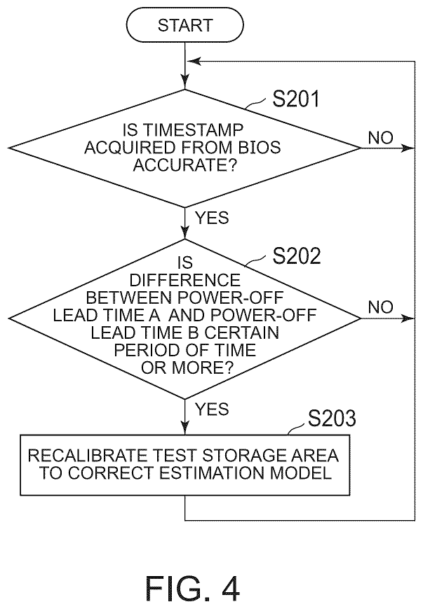

Referring next to FIG. 4, correction processing of the estimation model of the SSD 40 will be described.

FIG. 4 is a flowchart illustrating an example of the correction processing of the estimation model of the SSD 40 according to the present embodiment.

As illustrated in FIG. 4, the correction processing unit 67 of the control unit 60 determines whether or not the timestamp acquired from the BIOS is accurate (step S201). When the timestamp acquired from the BIOS (the BIOS timestamp) is accurate (step S201: YES), the correction processing unit 67 advances the processing to step S202. On the other hand, when the timestamp acquired from the BIOS (the BIOS timestamp) is not accurate (step S201: NO), the correction processing unit 67 returns the processing to step S201.

In step S202, the correction processing unit 67 determines whether or not a difference between the power-off lead time A and the power-off lead time B is a certain period of time or more. When the difference between the power-off lead time A and the power-off lead time B is the certain period of time or more (step S202: YES), the correction processing unit 67 advances the processing to step S203. On the other hand, when the difference between the power-off lead time A and the power-off lead time B is less than the certain period of time (step S202: NO), the correction processing unit 67 returns the processing to step S201.

In step S203, the correction processing unit 67 recalibrates the test storage area 53 to correct the estimation model. The correction processing unit 67 corrects the estimation model so that the power-off lead time A and the power-off lead time B match each other. For example, the correction processing unit 67 corrects the estimation model by adjusting the activation energy H in Equation (1) described above so that the power-off lead time A and the power-off lead time B match each other. The correction processing unit 67 stores the corrected estimation model in the estimation model storage area 55. After the process in step S203, the correction processing unit 67 returns the processing to step S201.

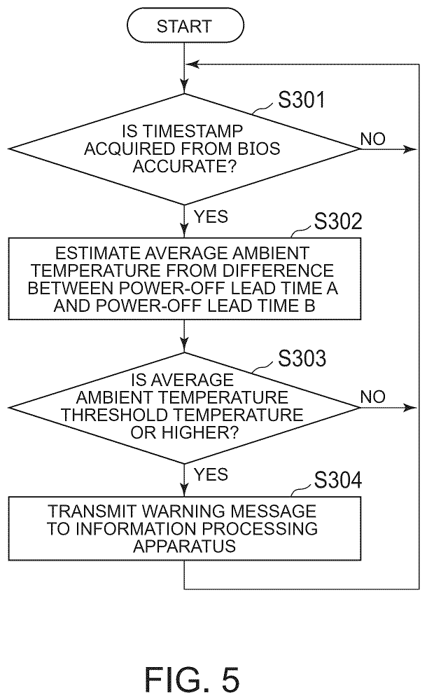

Referring next to FIG. 5, warning processing of the SSD 40 will be described.

FIG. 5 is a flowchart illustrating an example of the warning processing of the SSD 40 according to the present embodiment.

As illustrated in FIG. 5, the warning processing unit 68 of the control unit 60 determines whether or not the timestamp acquired from the BIOS is accurate (step S301). When the timestamp acquired from the BIOS (the BIOS timestamp) is accurate (step S301: YES), the warning processing unit 68 advances the processing to step S302. On the other hand, when the timestamp acquired from the BIOS (the BIOS timestamp) is not accurate (step S301: NO), the warning processing unit 68 returns the processing to step S301.

In step S302, the warning processing unit 68 estimates an average ambient temperature from a difference between the power-off lead time A and the power-off lead time B. For example, the warning processing unit 68 estimates the average ambient temperature of the information processing apparatus 100 (upper apparatus) using Equation (1) described above.

Next, the warning processing unit 68 determines whether or not the average ambient temperature is a threshold temperature or higher (step S303). When the average ambient temperature is the threshold temperature or higher (step S303: YES), the warning processing unit 68 advances the processing to step S304. On the other hand, when the average ambient temperature is lower than the threshold temperature (step S303: NO), the warning processing unit 68 returns the processing to step S301.

In step S304, the warning processing unit 68 transmits a warning message to the information processing apparatus 100. For example, the warning processing unit 68 transmits, to the main control unit 10, a message warning that the average ambient temperature exceeding the upper limit of the guaranteed storage temperature has been stored as the warning message to output the message to the information processing apparatus 100. After the process in step S304, the warning processing unit 68 returns the processing to step S301.

As described above, the SSD 40 (memory drive device) according to the present embodiment is a memory drive device having rewritable flash memory chips 41 (non-volatile memory chips), which includes the data storage area 51, the test storage area 53, and the control unit 60. The data storage area 51 is composed of the flash memory chips 41, which is an area capable of storing data used in information processing. The test storage area 53 is composed of the flash memory chips 41 to store predetermined test data. The control unit 60 performs rewriting of already-stored data on the data storage area 51 when the predetermined data retention period has been reached. The control unit 60 calculates a power-off lead time (a power-off period) of the upper apparatus (the information processing apparatus 100) based on the BIOS timestamp (date and time information) acquired from the upper apparatus to which the SSD 40 is connected, and when the acquired BIOS timestamp is accurate and the power-off lead time exceeds the threshold period, the control unit 60 determines that the predetermined data retention period has been reached. When the timestamp is not accurate, the control unit 60 determines that the predetermined data retention period has been reached based on an index value (for example, the BER) related to a storage failure in the test storage area 53 in which predetermined test data are stored in advance.

Thus, the SSD 40 (memory drive device) according to the present embodiment makes the determination that the predetermined data retention period has been reached by switching determination criteria between the power-off lead time (power-off period) based on the BIOS timestamp (date and time information) acquired from the upper apparatus (the information processing apparatus 100) and the index value (for example, the BER). Therefore, since the SSD 40 (memory drive device) according to the present embodiment can make the determination that the predetermined data retention period has been reached properly and reliably, rewriting can be performed on the data storage area 51 properly before data are garbled, thus enabling garbled data due to retention characteristics to be reduced and reliability to be improved.

Further, in the present embodiment, the control unit 60 calculates the power-off lead time based on the BIOS timestamp (first date and time information) as the timestamp acquired from the BIOS of the upper apparatus upon bootup of the upper apparatus, and the power-off timestamp (second date and time information) as the timestamp when the SSD 40 is powered off. Further, the control unit 60 determines whether or not the acquired BIOS timestamp is accurate based on the time relationship between the BIOS timestamp and the power-off timestamp.

Thus, the SSD 40 according to the present embodiment can calculate the power-off lead time easily depending on the BIOS timestamp (first date and time information) and the power-off timestamp (second date and time information). Further, the SSD 40 according to the present embodiment can determine whether or not the BIOS timestamp is accurate properly depending on the time relationship between the BIOS timestamp and the power-off timestamp. Therefore, the SSD 40 according to the present embodiment can use the power-off lead time calculated from the BIOS timestamp properly to reduce garbled data due to retention characteristics and to improve reliability.

Further, in the present embodiment, the bit error rate (BER) when reading test data of the test storage area 53 is included as the index value. When the BIOS timestamp is not accurate, the control unit 60 determines that the predetermined data retention period has been reached based on the bit error rate (BER) as the index value.

Thus, for example, during the period when the information processing apparatus 100 is not booted up or even when the occurrence of a temperature change cannot be grasped, the SSD 40 according to the present embodiment can accurately determine the possibility of garbled data due to retention by using the bit error rate (BER). Therefore, the SSD 40 according to the present embodiment can reduce garbled data due to the retention characteristics of the flash memory chips 41 more properly.

Further, in the present embodiment, when the BIOS timestamp is accurate, the control unit 60 adopts, as the power-off lead time, the longer one between the power-off lead time A (first power-off period) calculated based on the BIOS timestamp and the power-off timestamp, and the power-off lead time B (second power-off period) estimated based on the bit error rate (BER). On the other hand, when the BIOS timestamp is not accurate, the control unit 60 adopts the power-off lead time B as the power-off lead time. When the power-off lead time exceeds the threshold period, the control unit 60 determines that the predetermined data retention period has been reached, and performs rewriting of already-stored data on the data storage area 51.

Thus, the SSD 40 according to the present embodiment can use the more proper one between the power-off lead time A (first power-off period) and the power-off lead time B (second power-off period) to determine that the predetermined data retention period has been reached properly and accurately, and hence can reduce garbled data due to the retention characteristics of the flash memory chips 41 more properly.

Further, the SSD 40 according to the present embodiment includes the warning processing unit 68. When the acquired BIOS timestamp is accurate, the warning processing unit 68 estimates the average ambient temperature of the upper apparatus based on the difference between the power-off lead time A and the power-off lead time B, and when the average ambient temperature is the threshold temperature or higher, the warning processing unit 68 outputs information indicative of a warning to the upper apparatus. Here, for example, the threshold temperature is a predetermined temperature exceeding the upper limit of the guaranteed storage temperature of the SSD 40.

Thus, the SSD 40 according to the present embodiment can output a warning to the user when the SSD 40 is stored in a high temperature environment such as an environment beyond the upper limit of the guaranteed storage temperature of the SSD 40.

Further, in the present embodiment, the control unit 60 estimates the power-off lead time B using the estimation model for estimating the power-off lead time from the bit error rate. The SSD 40 according to the present embodiment includes the correction processing unit 67. When the difference between the power-off lead time A and the power-off lead time B is the certain period of time or more, the correction processing unit 67 corrects the estimation model so that the power-off lead time A and the power-off lead time B match each other.

Thus, when the difference between the power-off lead time A based on the BIOS timestamp and the power-off lead time B based on the BER becomes large, the SSD 40 according to the present embodiment can correct the estimation model properly, and hence the estimation accuracy of the power-off lead time can be improved.

Further, the information processing apparatus 100 according to the present embodiment is the upper apparatus including the SSD 40 described above to execute information processing using data stored in the SSD 40.

Thus, since the information processing apparatus 100 according to the present embodiment has the same effects as the SSD 40 according to the present embodiment described above, garbled data due to retention characteristics can be reduced and reliability can be improved.

Further, a control method according to the present embodiment is a control method for the SSD 40 having the rewritable flash memory chips 41 and including: the data storage area 51 composed of the flash memory chips 41 and capable of storing data used in information processing; and the test storage area 53 composed of the flash memory chips 41 to store predetermined test data, the control method including a first processing step, a second processing step, and a third processing step. In the first processing step, the control unit 60 calculates the power-off lead time of the upper apparatus based on the BIOS timestamp acquired from the upper apparatus (the information processing apparatus 100) to which the SSD 40 is connected, and when the acquired BIOS timestamp is accurate and the power-off lead time exceeds the threshold period, the control unit 60 determines that the predetermined data retention period has been reached. In the second processing step, when the BIOS timestamp is not accurate, the control unit 60 determines that the predetermined data retention period has been reached based on an index value (for example, the BER) related to a storage failure in the test storage area 53 in which predetermined test data are stored in advance. In the third processing step, when the predetermined data retention period has been reached, the control unit 60 performs rewriting of already-stored data on the data storage area 51.

Thus, since the control method according to the present embodiment has the same effects as the SSD 40 according to the present embodiment described above, garbled data due to retention characteristics can be reduced and reliability can be improved.

### Second Embodiment

Next, an SSD 40a according to a second embodiment will be described with reference to the accompanying drawings. In the second embodiment, a modification of making a determination that the predetermined data retention period has been reached based on the BER without using the power-off lead time will be described.

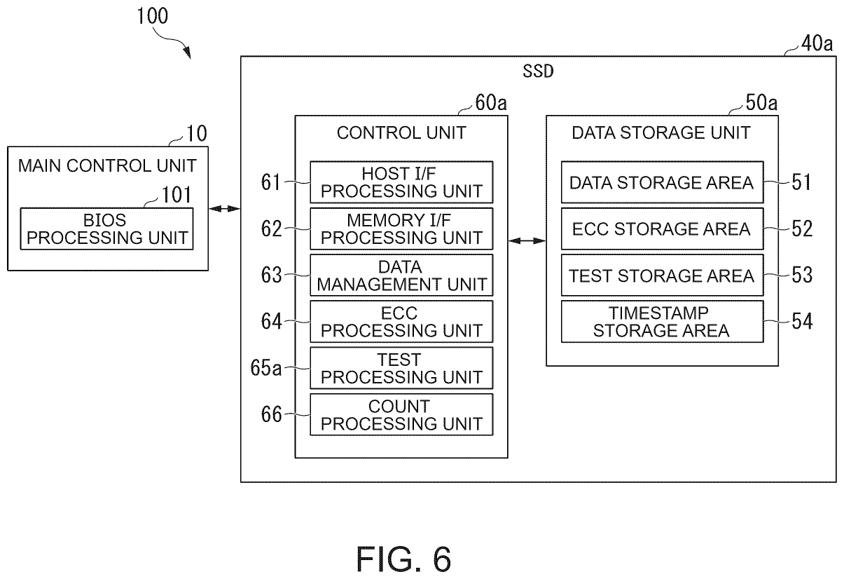

FIG. 6 is a block diagram illustrating an example of the functional configuration of the SSD 40a according to the present embodiment.

As illustrated in FIG. 6, the SSD 40a (another example of the memory drive device) includes a data storage unit 50a and a control unit 60a.

Note that in this figure, the same components as those in FIG. 2 are given the same symbols, and the description thereof will be omitted. Further, since the hardware configuration of the SSD 40a and the information processing apparatus 100 according to the present embodiment is the same as that in the first embodiment illustrated in FIG. 1, the description thereof is omitted here.

The data storage unit 50a is a storage unit composed of the plural flash memory chips 41 described above, which includes, for example, the data storage area 51, the ECC storage area 52, the test storage area 53, and the timestamp storage area 54.

In the present embodiment, the data storage unit 50a is different from the data storage unit 50 in the first embodiment in that the estimation model storage area 55 is not included.

The control unit 60a is a functional unit implemented by the memory controller 42 described above, which executes various processing of the SSD 40a. The control unit 60a includes the host I/F processing unit 61, the memory I/F processing unit 62, the data management unit 63, the ECC processing unit 64, a test processing unit 65a, and the count processing unit 66.

In the present embodiment, the control unit 60a is different from the control unit 60 in the first embodiment in that the correction processing unit 67 and the warning processing unit 68 are not included, and processing by the test processing unit 65a is different.

When the BIOS timestamp is accurate, the test processing unit 65a calculates the power-off lead time based on the BIOS timestamp. When the BIOS timestamp is accurate and the power-off lead time exceeds the threshold period, the test processing unit 65a determines that the predetermined data retention period has been reached, and performs rewriting of already-stored data on the data storage area 51.

Further, the test processing unit 65a calculates a BER for the test storage area 53, and when the BIOS timestamp is not accurate and the BER has reached a predetermined threshold indicating that the predetermined data retention period has been reached, the test processing unit 65a determines that the predetermined data retention period has been reached, and performs rewriting of already-stored data on the data storage area 51.

Since the details of the calculation process of the power-off lead time and the details of the calculation process of the BER by the test processing unit 65a are the same as those of the test processing unit 65 of the first embodiment described above, the description thereof is omitted here.

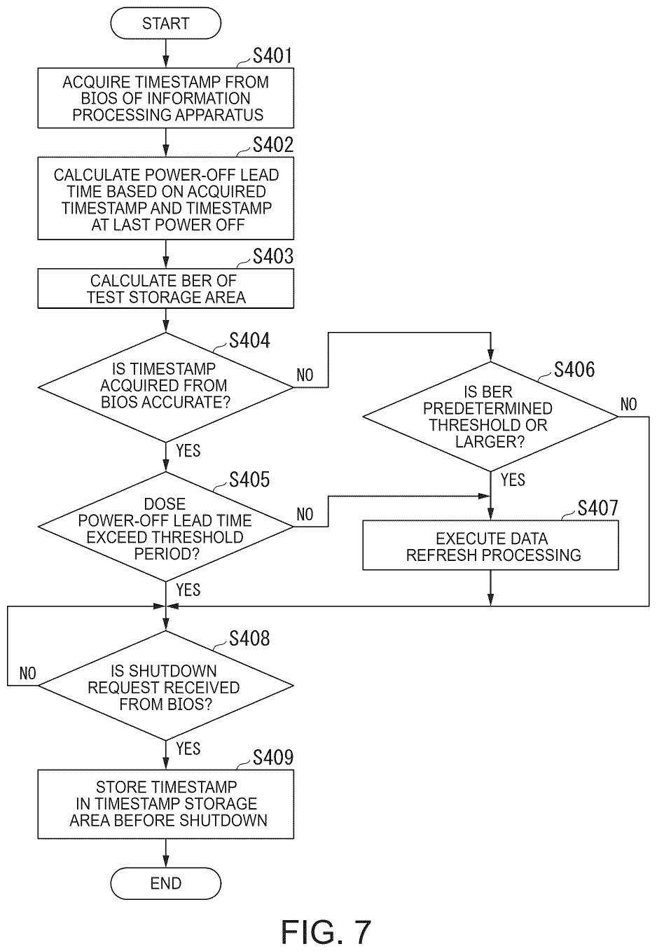

Referring next to FIG. 7, the operation of the SSD 40a according to the present embodiment will be described.

FIG. 7 is a flowchart illustrating an example of the operation of the SSD 40a according to the present embodiment. Here, processing in which the SSD 40a prevents garbled data due to retention will be described.

In FIG. 7, since processes from step S401 to step S403 are similar to the processes from step S101 to step S103 illustrated in FIG. 3 described above, the description thereof is omitted here. Note that in the present embodiment, the test processing unit 65a calculates the power-off lead time A as the power-off lead time in step S402.

Next, in step S404, the test processing unit 65a determines whether or not the timestamp acquired from the BIOS is accurate. For example, the test processing unit 65a determines whether or not the acquired BIOS timestamp is accurate depending on whether or not there is a contradiction between the acquired BIOS timestamp and the timestamp stored in the timestamp storage area 54. In other words, the test processing unit 65a determines whether or not the acquired BIOS timestamp is accurate based on a time relationship between the BIOS timestamp and the power-off timestamp. When the BIOS timestamp is accurate (step S404: YES), the test processing unit 65a advances the processing to step S405. On the other hand, when the BIOS timestamp is not accurate (step S404: NO), the test processing unit 65a advances the processing to step S406.

In step S405, the test processing unit 65a determines whether or not the power-off lead time exceeds the threshold period. When the power-off lead time exceeds the threshold period (step S405: YES), the test processing unit 65a determines that the predetermined data retention period has been reached, and advances the processing to step S408. On the other hand, when the power-off lead time does not exceed the threshold period (when the power-off lead time is the threshold period or less) (step S405: NO), the test processing unit 65a determines that the predetermined data retention period has not been reached, and advances the processing to step S407.

Further, in step S406, the test processing unit 65a determines whether or not the BER is the predetermined threshold or larger. Here, the predetermined threshold is a value indicating that the predetermined data retention period has been reached. In other words, the test processing unit 65a determines whether or not the predetermined data retention period has been reached based on the BER. When the BER is the predetermined threshold or larger (step S406: YES), the test processing unit 65a advances the processing to step S407. On the other hand, when the BER is smaller than the predetermined threshold (step S406: NO), the test processing unit 65a advances the processing to step S408.

In step S407, the test processing unit 65a executes data refresh processing. For example, the test processing unit 65a saves the data already stored in the data storage area 51 to the buffer storage unit configured by the unillustrated RAM, and rewrites (restores) the data through the memory I/F processing unit 62.

Since subsequent processes in step S408 and step S409 are the same as the processes in step S110 and step S111 illustrated in FIG. 3 described above, the description thereof is omitted here.

As described above, the SSD 40a according to the present embodiment includes the data storage area 51, the test storage area 53, and the control unit 60a. The control unit 60a calculates the power-off lead time (power-off period) of the upper apparatus based on the BIOS timestamp (date and time information) acquired from the upper apparatus to which the SSD 40a is connected, and when the acquired BIOS timestamp is accurate and the power-off lead time exceeds the threshold period, the control unit 60a determines that the predetermined data retention period has been reached. On the other hand, when the timestamp is not accurate, the control unit 60a determines that the predetermined data retention period has been reached based on an index value (for example, the BER) related to a storage failure in the test storage area 53 in which predetermined test data are stored in advance. When the predetermined data retention period has been reached, the control unit 60a performs rewriting of already-stored data on the data storage area 51.

Thus, like the SSD 40 of the first embodiment described above, the SSD 40a according to the present embodiment can perform rewriting on the data storage area 51 properly before data are garbled, thus enabling garbled data due to retention characteristics to be reduced and reliability to be improved.

Further, in the present embodiment, when the BIOS timestamp is not accurate and the bit error rate (BER) has reached the predetermined threshold indicating that the predetermined data retention period has been reached, the control unit 60a performs rewriting of already-stored data on the data storage area 51.

Thus, since the SSD 40a according to the present embodiment has the same effects as the SSD 40 of the first embodiment described above, garbled data due to retention characteristics can be reduced and reliability can be improved.

### Third Embodiment

Next, an SSD 40b according to a third embodiment will be described with reference to the accompanying drawings.

In the third embodiment, another modification of the second embodiment to determine that the predetermined data retention period has been reached based on the amount of change in index value (BER) will be described.

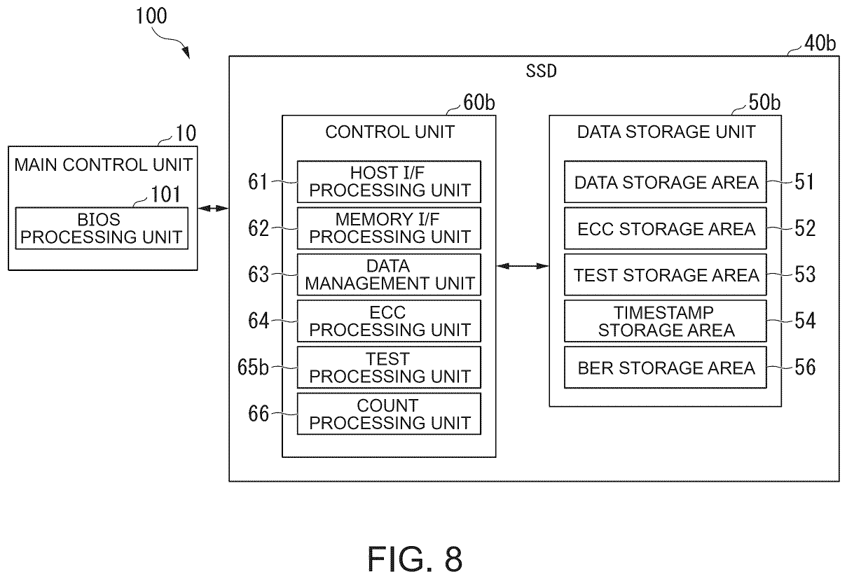

FIG. 8 is a block diagram illustrating an example of the functional configuration of the SSD 40b according to the present embodiment.

As illustrated in FIG. 8, the SSD 40b (still another example of the memory drive device) includes a data storage unit 50b and a control unit 60b.

Note that in this figure, the same components as those in FIG. 6 are given the same symbols, and the description thereof will be omitted. Further, since the hardware configuration of the SSD 40b and the information processing apparatus 100 according to the present embodiment is the same as that in the first embodiment illustrated in FIG. 1, the description thereof is omitted here.

The data storage unit 50b is a storage unit composed of the plural flash memory chips 41 described above, which includes, for example, the data storage area 51, the ECC storage area 52, the test storage area 53, the timestamp storage area 54, and a BER storage area 56.

The BER storage area 56 is composed of the flash memory chips 41 to store the initial value of the BER of the test storage area 53. Note that the initial value of the BER is updated when data rewriting is performed on the data storage area 51 by a test processing unit 65b.

The control unit 60b is a functional unit implemented by the memory controller 42 described above to execute various processing of the SSD 40b. The control unit 60b includes the host I/F processing unit 61, the memory I/F processing unit 62, the data management unit 63, the ECC processing unit 64, the test processing unit 65b, and the count processing unit 66.

When the BIOS timestamp is accurate, the test processing unit 65b calculates the power-off lead time based on the BIOS timestamp. When the BIOS timestamp is accurate and the power-off lead time exceeds the threshold period, the test processing unit 65b determines that the predetermined data retention period has been reached, and performs rewriting of already-stored data on the data storage area 51.

Further, the test processing unit 65b calculates the BER for the test storage area 53, and when the BIOS timestamp is not accurate and the amount of BER change has reached the predetermined threshold indicating that the predetermined data retention period has been reached, the test processing unit 65b determines that the predetermined data retention period has been reached, and performs rewriting of already-stored data on the data storage area 51.

For example, the test processing unit 65b calculates the BER of the test storage area 53 and acquires the initial value of the BER stored in the BER storage area 56. When the amount of BER change from the initial value of the calculated BER becomes a predetermined threshold ΔR1 or larger, the test processing unit 65b determines that the predetermined data retention period has been reached. Here, for example, the predetermined threshold ΔR1 is set as an amount of BER change corresponding to a period during which errors in data of the test storage area 53 can be corrected in the error correction processing by the ECC processing unit 64 based, for example, on the retention characteristics (relationship characteristics between the passage of time and garbled data) in the flash memory chips 41.

Further, when the amount of BER change becomes the predetermined threshold ΔR1 or larger, the test processing unit 65b performs rewriting of already-stored data on the data storage area 51, and updates the initial value of the BER stored in the BER storage area 56 to the calculated current BER value.

Note that the process of the test processing unit 65b in the present embodiment is different from that in the second embodiment in that the process is changed to a process of determining that predetermined data retention period has been reached due to the amount of change in the index value (BER) described above. The other processes are the same as those of the test processing unit 65a of the second embodiment.

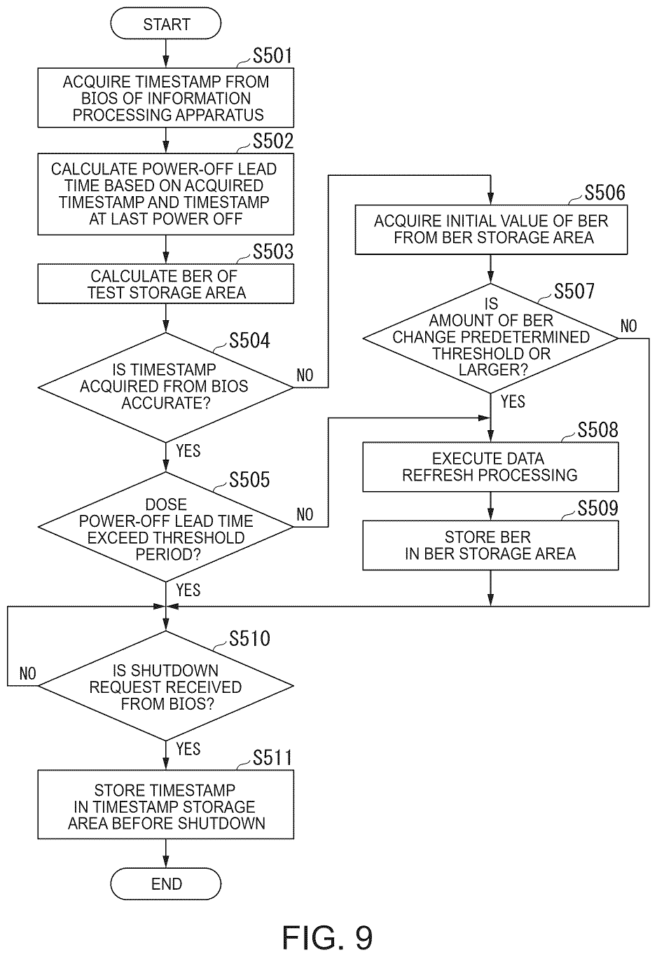

Referring next to FIG. 9, the operation of the SSD 40b according to the present embodiment will be described.

FIG. 9 is a flowchart illustrating an example of the operation of the SSD 40b according to the present embodiment. Here, processing in which the SSD 40b prevents garbled data due to retention will be described.

In FIG. 9, since processes from step S501 to step S505 are the same as the processes from step S401 to step S405 illustrated in FIG. 7 described above, the description thereof is omitted here.

In step S506, the test processing unit 65b acquires the initial value of the BER (past BER value) from the BER storage area 56. The test processing unit 65b acquires the initial value of the BER stored in the BER storage area 56 through the memory I/F processing unit 62.

Next, the test processing unit 65b determines whether or not the amount of BER change is the predetermined threshold ΔR1 or larger (step S507). Here, the predetermined threshold ΔR1 is a value indicating that the predetermined data retention period has been reached. The test processing unit 65b calculates the amount of BER change from a difference between the calculated BER and the initial value of the BER, and determines whether or not the amount of BER change is the predetermined threshold ΔR1 or larger. When the amount of BER change is the predetermined threshold ΔR1 or larger (step S507: YES), the test processing unit 65b advances the processing to step S508. On the other hand, when the amount of BER change is smaller than the predetermined threshold ΔR1 (step S507: NO), the test processing unit 65b advances the processing to step S510.

In step S508, the test processing unit 65b performs data rewriting on the data storage area 51. The test processing unit 65b executes the same processing as that in step S109 of FIG. 3 described above.

Next, the test processing unit 65b stores the BER in the BER storage area 56 (step S509). In other word, the test processing unit 65b updates the initial value of the BER stored in the BER storage area 56 to the calculated current BER value. After the process in step S509, the test processing unit 65b advances the processing to step S510.

Since subsequent processes in step S510 and step S511 are the same as the processes in step S408 and step S409 illustrated in FIG. 7 described above, the description thereof is omitted here.

Note that, when the predetermined data retention period has been reached, the test processing unit 65b may also perform rewriting of already-stored data on the data storage area 51 and the test storage area 53.

As described above, in the present embodiment, when the BIOS timestamp is not accurate and the amount of change in the bit error rate (BER) has reached the predetermined threshold ΔR1 indicating that the predetermined data retention period has been reached, the control unit 60b performs rewriting of already-stored data on the data storage area 51.

Thus, since the SSD 40b (memory drive device) and the information processing apparatus 100 according to the present embodiment have the same effects as those in the first and second embodiments described above, garbled data due to the retention characteristics of the flash memory chips 41 can be reduced and reliability can be improved.

Note that the present invention is not limited to each of the aforementioned embodiments, and changes can be made without departing from the scope of the present invention.

For example, in each of the aforementioned embodiments, the example in which the information processing apparatus 100 is a laptop personal computer is described, but the information processing apparatus 100 is not limited to this example. For example, the information processing apparatus 100 may also be any other type of information processing apparatus such as a desktop personal computer, a tablet terminal, or the like.

Further, in each of the aforementioned embodiments, the example in which the BER is used as the index value indicative of the rate of storage failure in the test storage area 53 is described, but the present invention is not limited to this example, and any other index value such as a cell applied voltage as an applied voltage value corresponding to a change in cell VT voltage. Further, for example, in each of the aforementioned embodiments, a combination of the BER and the cell applied voltage may be used as index values.

Further, in each of the aforementioned embodiments, the example in which the processes by the control unit 60 (60a, 60b) (the test processing unit 65 (65a, 65b)) are executed as internal processes of the SSD 40 (40a, 40b) is described, but the present invention is not limited to this example, and some of the processes of the test processing unit 65 (65a, 65b) may also be executed by the information processing apparatus 100.

Further, in each of the aforementioned embodiments, the example in which the test processing unit 65 (65a, 65b) consecutively executes the determination process that the predetermined data retention period has been reached and the rewrite process of performing rewriting on the data storage area 51 is described, but the present invention is not limited to this example, and the determination process and the rewrite process may also be executed separately from each other. For example, the test processing unit 65 (65a, 65b) may also execute the rewrite process using, as a trigger, background media scan of the SSD 40 (40a, 40b).

Further, the test processing unit 65 (65a, 65b) may execute the rewrite process on blocks (or pages) of the flash memory chips 41 where data of the data storage area 51 are written. Further, for example, the test processing unit 65 (65a, 65b) may detect blocks (or pages) high in the BER and rescued by the ECC function from the data storage area 51 to execute the rewrite process on the blocks (or the pages) high in the detected BER or the like.

Further, in each of the aforementioned embodiments, the example in which the SSD 40 (40a, 40b) includes the ECC processing unit 64 as the functional unit implemented by the memory controller 42 is described, but the present invention is not limited to this example. For example, the ECC processing unit 64 may also be provided by the flash memory chips 41.

Note that each of the SSD 40 (40a, 40b) and the information processing apparatus 100 described above has a computer system therein. Then, a program for implementing the functions of each of the SSD 40 (40a, 40b) and the information processing apparatus 100 described above may be recorded on a computer-readable recording medium so that the program recorded on this recording medium is read into the computer system and executed to perform processing in each of the SSD 40 (40a, 40b) and the information processing apparatus 100 described above. Here, the fact that “the program recorded on the recording medium is read into the computer system and executed” includes installing the program on the computer system. It is assumed that the “computer system” here includes the OS and hardware such as peripheral devices and the like.

Further, the “computer system” may also include two or more computers connected through networks including the Internet, WAN, LAN, and a communication line such as a dedicated line. Further, the “computer-readable recording medium” means a portable medium such as a flexible disk, a magneto-optical disk, a flash ROM, or a CD-ROM, or a storage device such as a hard disk built in the computer system. Thus, the recording medium with the program stored thereon may be a non-transitory recording medium such as the CD-ROM.

Further, a recording medium internally or externally provided to be accessible from a delivery server for delivering the program is included as the recording medium. Note that the program may be split into plural pieces, downloaded at different timings, respectively, and then united in each of the SSD 40 (40a, 40b) and the information processing apparatus 100, or delivery servers for delivering respective split pieces of the program may be different from one another. Further, it is assumed that the “computer-readable recording medium” includes a medium on which the program is held for a given length of time, such as a volatile memory (RAM) inside a computer system as a server or a client when the program is transmitted through a network. The above-mentioned program may also be to implement some of the functions described above. Further, the program may be a so-called a differential file (differential program) capable of implementing the above-described functions in combination with a program(s) already recorded in the computer system.

Further, some or all of the functions described above may be realized as an integrated circuit such as LSI (Large Scale Integration). Each function described above may be implemented by a processor individually, or some or all of the functions may be integrated as a processor. Further, the method of circuit integration is not limited to LSI, and may be realized by a dedicated circuit or a general-purpose processor. Further, if integrated circuit technology replacing the LSI appears with the progress of semiconductor technology, an integrated circuit according to the technology may be used.

### DESCRIPTION OF SYMBOLS

10 main control unit
11 CPU
12 main memory
13 video subsystem
14 display unit
21 chipset
22 BIOS memory
31 embedded controller (EC)
32 input unit
33 power supply circuit
40, 40a, 40b SSD
41 flash memory chip
42 memory controller
50, 50a, 50b data storage unit
51 data storage area
52 ECC storage area
53 test storage area
54 timestamp storage area
55 estimation model storage area
56 BER storage area
60, 60a, 60b control unit
61 host I/F processing unit
62 memory I/F processing unit
63 data management unit
64 ECC processing unit
65, 65a, 65b test processing unit
67 correction processing unit
68 warning processing unit
100 information processing apparatus

What is claimed is:

1. A memory drive device having rewritable non-volatile memory chips, the memory drive device comprising:
a data storage area composed of the non-volatile memory chips and configured to store data used in information processing;
a test storage area composed of the non-volatile memory chips to store predetermined test data; and
a controller which performs rewriting of already-stored data on the data storage area when a predetermined data retention period has been reached, wherein
the controller calculates a power-off period of an upper apparatus based on date and time information acquired from the upper apparatus to which the memory drive device is connected, and when the acquired date and time information is accurate and the power-off period exceeds a threshold period, the controller determines that the predetermined data retention period has been reached, or
when the date and time information is not accurate, the controller determines that the predetermined data retention period has been reached based on an index value related to a storage failure in the test storage area in which the predetermined test data are stored in advance.

2. The memory drive device according to claim 1, wherein
the controller calculates the power-off period based on first date and time information as the date and time information acquired from a BIOS (Basic Input Output System) of the upper apparatus upon bootup of the upper apparatus, and second date and time information as date and time information upon power-off of the memory drive device, and
the controller determines whether or not the acquired date and time information is accurate based on a time relationship between the first date and time information and the second date and time information.

3. The memory drive device according to claim 2, wherein
a bit error rate when reading the test data of the test storage area is included as the index value, and
when the date and time information is not accurate, the controller determines that the predetermined data retention period has been reached based on the bit error rate as the index value.

4. The memory drive device according to claim 3, wherein
when the date and time information is accurate, the controller adopts, as the power-off period, longer one between a first power-off period calculated based on the first date and time information and the second date and time information, and a second power-off period estimated based on the bit error rate, or
when the date and time information is not accurate, the controller adopts the second power-off period as the power-off period, and
when the power-off period exceeds the threshold period, the controller determines that the predetermined data retention period has been reached, and performs rewriting of already-stored data on the data storage area.

5. The memory drive device according to claim 4, further comprising a warning processing unit which estimates an average ambient temperature of the upper apparatus based on a difference between the first power-off period and the second power-off period when the acquired date and time information is accurate, and when the average ambient temperature is a threshold temperature or higher, the warning processing unit outputs information indicative of a warning to the upper apparatus.

6. The memory drive device according to claim 4, wherein
the controller estimates the second power-off period using an estimation model for estimating the power-off period from the bit error rate, and
the memory drive device further comprises a correction processing unit which corrects the estimation model so that the first power-off period and the second power-off period match each other when a difference between the first power-off period and the second power-off period is a certain period or more.

7. The memory drive device according to claim 3, wherein when the date and time information is not accurate and the bit error rate has reached a predetermined threshold indicating that the predetermined data retention period has been reached, the controller performs rewriting of already-stored data on the data storage area.

8. The memory drive device according to claim 3, wherein when the date and time information is not accurate and an amount of change in the bit error rate has reached a predetermined threshold indicating that the predetermined data retention period has been reached, the controller performs rewriting of already-stored data on the data storage area.

9. An information processing apparatus including the memory drive device according to claim 1, which is an upper apparatus to execute information processing using data stored in the memory drive device.

10. A control method for a memory drive device having rewritable non-volatile memory chips and including: a data storage area composed of the non-volatile memory chips and configured to store data used in information processing; and a test storage area composed of the non-volatile memory chips to store predetermined test data, the control method comprising:
causing a controller to calculate a power-off period of an upper apparatus based on date and time information acquired from the upper apparatus to which the memory drive device is connected, and to determine that a predetermined data retention period has been reached when the acquired date and time information is accurate and the power-off period exceeds a threshold period;
causing the controller to determine that the predetermined data retention period has been reached based on an index value related to a storage failure in the test storage area in which the predetermined test data are stored in advance when the date and time information is not accurate; and
causing the controller to perform rewriting of already-stored data on the data storage area when the predetermined data retention period has been reached.
